(19) United States
(12) Patent Application Publication
(10) Pub. No.: US 2005/0127421 A1
(43) Pub. Date: Jun. 16, 2005

(54) Semiconductor module having an insulation layer and method for fabricating a semiconductor module having an insulation layer

(75) Inventors: Harald Seidl, Poering (DE); Jorn Lutzen, Dresden (DE); Gerhard Beitel, Munchen (DE); Thomas Hecht, Dresden (DE); Annette Sanger, Dresden (DE); Albert Birner, Dresden (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munich (DE)

(21) Appl. No.: 10/502,930

(22) PCT Filed: Jan. 16, 2003
(86) PCT No.: PCT/EP03/00377

(30) Foreign Application Priority Data
Jan. 30, 2002 (DE) 102 03 674.8

(51) Int. Cl. H01L 27/108

(52) U.S. Cl. 257/300

(57) ABSTRACT

A semiconductor module is described which is essentially constructed from a silicon material and has an insulation layer for example in the form of a gate insulation layer or a MOS transistor or in the form of an insulation layer of a memory cell for a dynamic memory module. The insulation layer preferably comprises a dielectric material whose band gap is greater than the band gap of SiO₂. To construct the insulation layer, use is made of materials which have a metal-fluorine compound, such as e.g. lithium fluoride. Particularly thin insulation layers are provided by the material described.

### CLAIM FOR PRIORITY

This application is a national stage application under 371 of PCT/EP03/00377, filed on Jan. 16, 2003, which claims the benefit of priority to German Application No. 102 03 674.8, which was filed on Jan. 30, 2002.

### TECHNICAL FIELD OF THE INVENTION

The invention relates to a semiconductor module, and in particular, to a module having an insulation layer and a method for fabricating same.

### BACKGROUND OF THE INVENTION

Semiconductor modules are used to produce electronic integrated circuits. Basic elements such as e.g. capacitors and transistors are used in this case. Insulator layers are particularly critical in this case, which layers must have specific properties with regard to capacitance and leakage current. A memory module has a multiplicity of memory cells which, in a simple embodiment, are formed from one transistor and one capacitor. The storage capacitor has, by way of example, a storage electrode, an insulating intermediate layer and a counterelectrode. Furthermore, transistors having an insulated gate electrode are used in the construction of electronic circuits. The increasing integration density requires a miniaturization of the geometries of the memory cell and of the transistor. However, this leads to a smaller capacitor area, which corresponds to a smaller capacitor capacitance. For a functional memory cell, however, it is necessary to comply with a minimum capacitance. A minimum capacitance can be complied with by making the insulating intermediate layer thinner, increasing the surface charge density of the capacitor area by means of alternative dielectrics, or increasing the capacitor area by means of suitable measures e.g. HSG (Hemispherical Silicon Grains). Materials having a higher dielectric constant than silicon oxide such as e.g. aluminium oxide, zirconium oxide or hafnium oxide, are currently being used as alternative dielectrics. In the case of the transistor, the miniaturization of the geometries leads to a thinner gate oxide layer, as a result of which the risk of electrical voltage flashovers and leakage currents is increased.

### SUMMARY OF THE INVENTION

The invention provides a semiconductor module having improved electrical properties and a method for fabricating a semiconductor module.

In one embodiment of the invention, there is a semiconductor module essentially comprising silicon, which has an insulation layer which is constructed from a dielectric material whose band gap is greater than that of SiO₂. The insulation layer is preferably used as a gate insulation layer or as an insulation layer of a capacitor. On account of the large band gap, the material according to the invention is suitable for forming insulation layers which have a relatively small leakage current and are robust with respect to voltage flashovers. As a result, insulation layers, for example in the case of a memory cell or in the case of a field-effect transistor, can be made thinner than when using SiOₓ or SiNₓ or combinations thereof, and the surface charge density can thus be increased.

In contrast to materials having larger dielectric constants, with the materials according to the invention which have a larger band gap for positive and negative charge carriers, insulator layers can be made thinner for the same leakage current.

Alkali metal halides or other metal-halogen compounds are preferably suitable for forming the insulation layer according to the invention.

Metal-fluorine compounds are suitable, in particular. Lithium fluoride, calcium fluoride, barium fluoride, magnesium fluoride or sodium fluoride is preferably used as the material. The abovementioned metal-fluorine compounds can be applied by means of epitaxial methods in the corresponding dimensions and patterned. Consequently, the metal-fluorine compounds are suitable for constructing an insulation layer which are used in particular in the fabrication of a semiconductor module constructed using silicon technology.

### BRIEF DESCRIPTION OF THE DRAWINGS

The invention is explained in more detail below with reference to the figures, in which:

FIG. 1 shows a memory cell.

FIG. 2 shows a MOS transistor.

FIG. 3 shows a table with preferred materials.

### DETAILED DESCRIPTION OF THE INVENTION

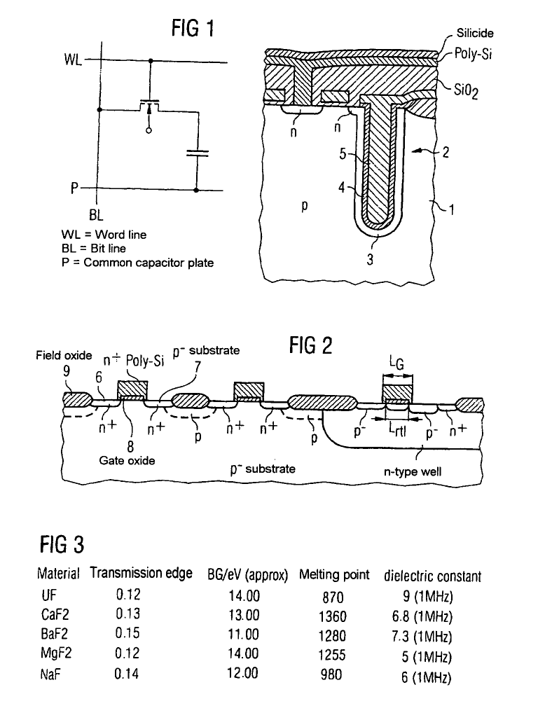

FIG. 1 shows the construction of a memory cell of a dynamic memory module in a diagrammatic illustration. The dynamic memory module has a multiplicity of memory cells which can be individually addressed via word lines and bit lines and selection transistors. The information held in the memory module is stored in the form of an electrical charge in the memory cell. The memory cell is constructed in the form of a trench capacitor. The trench capacitor stores an electrical charge which corresponds to a value of the information 0 or 1. Instead of a trench capacitor, it is also possible to use a different type of capacitor such as e.g. a stacked capacitor.

FIG. 1 shows a silicon substrate 1, into which is introduced a trench 2 surrounded with a first doping layer 3. An insulation layer 4 is formed in the trench 2 in a manner adjoining the first doping layer 3. The insulation layer 4 surrounds a conduction layer 5 which fills a large part of the trench 2. The first doping layer 3 and the conduction layer 5 constitute two capacitor areas. The insulation layer 4 constitutes a dielectric layer arranged between the capacitor areas. The silicon substrate 1 is positively doped in the exemplary embodiment illustrated. The first doping layer 3 is highly negatively doped and the conduction layer 5 is constructed from a negatively doped polysilicon material. The first doping layer 3 is connected to a bit line via a selection transistor, which can be driven via a word line. By means of corresponding driving of the selection transistor, the charge stored in the memory cell is transferred to the bit line. From the bit line, the charge is amplified by means of an output amplifier and output via output drivers to an output of the memory module.

The dielectric insulation layer 4 preferably comprises a material whose band gap is greater than that of SiO₂ (9.9 eV). The material used preferably has a dielectric constant which is likewise greater than that of SiO₂ or SiN or mixtures of the materials. Materials having an alkali metal halide compound are preferably used for the construction of the insulation layer 4, 8. In particular, metal fluoride compounds are suitable for the construction of the insulation layer.

Lithium fluoride (LiF), calcium fluoride (CaF), barium fluoride (BaF), magnesium fluoride (MgF) and sodium fluoride (NaF) are suitable for fabricating the insulation layer 4, 8 on account of the physical properties. Deposition methods such as e.g. chemical vapour deposition methods or ALD methods (Atomic Layer Deposition) are used as preferred fabrication method. Corresponding methods and the deposition of the abovementioned fluorine compounds are known to the person skilled in the art and described for example in “CVD of non-metals”, William S. Reeves, New York, VCH 1996, ISBN 3-527-29295-0” in Chapter 7.1 ff.

FIG. 2 shows a cross section through an integrated circuit of a semiconductor module which has a silicon substrate 1, into which a third and a fourth doping layer 6, 7 are introduced. Between the third and fourth doping layers 6, 7, a gate oxide layer 8 is applied on the silicon substrate 1. A conductive contact layer 9 is formed on the gate oxide layer 8. The silicon substrate 1 is positively doped. The third and fourth doping layers 6, 7 constitute negatively doped silicon regions. The gate oxide layer 8 is formed as an insulation layer which may be constructed from the same materials as the insulation layer 4 of the memory cell of FIG. 1. The contact layer 9 comprises a highly doped polysilicon material, metal or silicon/metal combinations. The dopings may also be formed in inverse fashion (p-type or n-type transistor).

The semiconductor structure illustrated in FIG. 2 shows a MOS transistor having the third and fourth doping layers 6, 7 as terminals and the contact layer 9 as gate terminal. On account of the preferred materials described above, the gate oxide layer 8 can be made very thin without large creepage currents or electrical damage to the gate oxide layer 8 occurring.

The dopings may also be inverse dopings. With increasing miniaturization, thinner layers are also possible.

On account of the materials according to the invention, the insulator layer can be made thinner than when using SiO₂ for the same leakage current, or with a lower leakage current for the same thickness.

FIG. 3 shows a table with characteristic parameters of a selection of materials which are suitable for the construction of the insulation layer according to the invention.

Lithium fluoride has a band gap of about 14 electronvolts and a dielectric constant of 9. Calcium fluoride has a band gap of about 13 electronvolts and a dielectric constant of 6.8. Barium fluoride has a band gap of about 11 electronvolts and a dielectric constant of 7.3. Magnesium fluoride has a band gap of about 14 electronvolts and a dielectric constant in the region of 5. Sodium fluoride has a band gap of about 12 electronvolts and a dielectric constant of 6. Depending on the embodiment, it is also possible to use mixtures or combinations of the materials according to the invention for the construction of an insulator layer. Furthermore, it is also possible to use combinations with other materials, such as e.g. aluminium oxide, for forming the insulation layer. In this case, the insulation layer is applied in the form of a plurality of layers.

The invention explained above uses the example of a memory cell of a dynamic memory module and a MOS transistor. However, the invention is not restricted to these circuits, but rather can be used for any type of circuit which is preferably constructed from a silicon material and in which a robust insulation layer is required. The insulation layer according to the invention can be used for any type of capacitor.

### List of Reference Symbols

1 Silicon substrate

2 Trench

3 1st doping layer

4 Insulation layer

5 Conduction layer

6 3rd doping layer

7 4th doping layer

8 Gate oxide

9 Contact layer

1. A semiconductor module, essentially made of silicon material, comprising:
an insulation layer formed as a gate insulation layer as an insulation layer of a capacitor, wherein
the insulation layer is constructed from a dielectric material whose band gap is greater than that of SiO₂, and the material has a sodium compound.

2. The semiconductor module according to claim 1, wherein the material has a dielectric constant which is greater than or equal to the dielectric constant of silicon oxide.

3. The semiconductor module according to claim 1, wherein the material has an alkali metal halide compound.

4. The semiconductor module according to claim 1, wherein the material has a metal-fluorine compound.

5. The semiconductor module according to claim 1, wherein the capacitor is part of a memory cell of a memory module.

6. A method for fabricating a semiconductor module, made essentially of silicon material,
comprising applying
a layer made of a dielectric material whose band gap is greater than the band gap of SiO₂ as an insulation layer.

7. The semiconductor module according to claim 2, wherein the material has an alkali metal halide compound.

8. The semiconductor module according to claim 2, wherein the material has a metal-fluorine compound.

9. The semiconductor module according to claim 3, wherein the material has a metal-fluorine compound.

10. The semiconductor module according to claim 2, wherein the capacitor is part of a memory cell of a memory module.

11. The semiconductor module according to claim 3, wherein the capacitor is part of a memory cell of a memory module.

12. The semiconductor module according to claim 4, wherein the capacitor is part of a memory cell of a memory module.
